(19) United States
(12) Patent Application Publication
(10) Pub. No.: US 2025/0160176 A1
(43) Pub. Date: May 15, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Hong CHEN, Beijing (CN); Ge WANG, Beijing (CN); Miao WANG, Beijing (CN); Zhiliang JIANG, Beijing (CN); Chenxi LI, Beijing (CN); Ge NIU, Beijing (CN); Xiang LUO, Beijing (CN); Dengyu WANG, Beijing (CN); Chunyan LI, Beijing (CN)

(21) Appl. No.: 18/832,915

(22) PCT Filed: Oct. 8, 2023
(86) PCT No.: PCT/CN2023/123339

§ 371 Date: Jul. 24, 2024

(30) Foreign Application Priority Data
Nov. 17, 2022 (CN) 202211460729.8

(51) Int. Cl. H10K 59/80

(52) U.S. Cl. CPC H10K 59/873

(57) ABSTRACT

A display substrate and a display device are provided. The display substrate includes a display area and a frame area, wherein the frame area is located around the display area, and the frame area is provided with a first barrier structure and a second barrier structure. In a direction perpendicular to the plane where the display substrate is located, the display substrate includes a base, and a driving structure layer, a light-emitting structure layer and an encapsulation structure layer, which are sequentially stacked on the base; the first barrier structure is arranged between the driving structure layer and the encapsulation structure layer, and the second barrier structure is arranged on the driving structure layer.

### CROSS-REFERENCE TO RELATED APPLICATIONS

The present application is a U.S. National Phase Entry of International Application PCT/CN2023/123339 having an international filing date of Oct. 8, 2023, which claims priority to Chinese Patent Application No. 202211460729.8, filed on Nov. 17, 2022, with the CNIPA, and entitled “Display Substrate and Display Device”, which are hereby incorporated herein by reference in their entireties.

### TECHNICAL FIELD

Embodiments of the disclosure relate, but are not limited, to the technical field of display, and in particular to a display substrate and a display device.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display device (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In a first aspect, the embodiment of the present disclosure provides a display substrate, including a display area and a bezel area, wherein the bezel area is located at a periphery of the display area, and the bezel area is provided with a first barrier structure and a second barrier structure; in a direction perpendicular to a plane where the display substrate is located, the display substrate includes a base substrate and a drive structure layer, a light emitting structure layer, and an encapsulation structure layer sequentially stacked on the base substrate, wherein the first barrier structure is disposed between the drive structure layer and the encapsulation structure layer, and the second barrier structure is disposed in the drive structure layer.

In an exemplary embodiment, each of the first barrier structure and the second barrier structure is in a strip shape, and extension directions of the first barrier structure and the second barrier structure are consistent with an extension direction of an edge of the display area.

In an exemplary embodiment, the first barrier structure includes a first barrier dam and a second barrier dam, and in a direction parallel to the plane where the display substrate is located, the bezel area includes a first barrier area and a second barrier area, the first barrier area is located between the display area and the first barrier dam, and the second barrier area is located between the first barrier dam and the second barrier dam; the second barrier structure is disposed at at least one position in the first barrier area and the second barrier area.

In an exemplary embodiment, in the direction perpendicular to the plane where the display substrate is located, a size of the first barrier structure is greater than or equal to a size of the second barrier structure, and a size of the second barrier dam is greater than or equal to a size of the first barrier dam; in an extension direction perpendicular to the edge of the display area, a size of the second barrier dam is greater than or equal to a size of the first barrier dam.

In an exemplary embodiment, the drive structure layer includes a first semiconductor layer, a first gate insulation layer, a first conductive layer, a second gate insulation layer, a second conductive layer, an interlayer insulation layer, a third conductive layer, a planarization layer, and a fourth conductive layer that are sequentially stacked on the base substrate, and the second barrier structure is disposed in one or more of the first semiconductor layer, the first conductive layer, and the second conductive layer.

In an exemplary embodiment, the second barrier structure is a single-layer structure, the second barrier structure includes a plurality of strip-like convex structures, the plurality of strip-like convex structures are disposed in one or more of the first semiconductor layer, the first conductive layer, and the second conductive layer; in the direction perpendicular to the plane where the display substrate is located, a size of any one of the convex structures is consistent with a thickness of a film layer on which the convex structure is located.

In an exemplary embodiment, the second barrier structure is a multilayer structure, and the second barrier structure includes a plurality of strip-like convex structures disposed in a plurality of film layers of the first semiconductor layer, the first conductive layer, and the second conductive layer.

In an exemplary embodiment, in the direction perpendicular to the plane where the display substrate is located, sizes of the plurality of strip-like convex structures are consistent, any one of the convex structures includes sub-convex structures located in the plurality of film layers, and orthographic projections of the plurality of sub-convex structures in a same convex structure on the base substrate are at least partially overlapped.

In an exemplary embodiment, in a direction away from the display area, and in any one of the first barrier area and the second barrier area, sizes of the plurality of strip-like convex structures are sequentially increased in the direction perpendicular to the plane where the display substrate is located.

In an exemplary embodiment, the second barrier structure includes a first convex structure disposed in the first semiconductor layer, a second convex structure disposed in the first semiconductor layer and the first conductive layer, and a third convex structure disposed in the first semiconductor layer, the first conductive layer and the second conductive layer.

In an exemplary embodiment, the second convex structure includes two second sub-convex structures located in the first semiconductor layer and the first conductive layer, respectively, and orthographic projections of the two second sub-convex structures on the base substrate are at least partially overlapped; the third convex structure includes three third sub-convex structures located in the first semiconductor layer, the first conductive layer, and the second conductive layer respectively, and orthographic projections of the three third sub-convex structures on the base substrate are at least partially overlapped.

In an exemplary embodiment, the second barrier structure further includes at least one strip-like groove structure disposed in one or more of the first gate insulation layer, the second gate insulation layer, and the interlayer insulation layer.

In an exemplary embodiment, in the direction parallel to the plane where the display substrate is located, and in the first barrier area, the at least one groove structure is located between the display area and the convex structures; in the second barrier area, the at least one groove structure is located between the first barrier dam and the convex structures.

In an exemplary embodiment, in any one of the first barrier area and the second barrier area, and in the direction perpendicular to the plane where the display substrate is located, heights of surfaces of the at least one groove structure and the convex structures in the second barrier structure on a side away from the base substrate are sequentially increased with respect to the base substrate.

In an exemplary embodiment, at least one of the third conductive layer and the fourth conductive layer extends to the bezel area in the direction parallel to the plane where the display substrate is located, at least one of the third conductive layer and the fourth conductive layer is provided with a second power supply line, and an orthographic projection of the second barrier structure on the base substrate is at least partially overlapped with an orthographic projection of the second power supply line on the base substrate.

In an exemplary embodiment, in the bezel area, a cross-sectional shape of an overlapping region between orthographic projections of the third conductive layer, the fourth conductive layer and the second barrier structure on the base substrate is consistent with a cross-sectional shape of the second barrier structure.

In an exemplary embodiment, the bezel area is provided with a date driver on array (GOA) circuit, and an orthographic projection of the GOA circuit on the base substrate is not overlapped with an orthographic projection of the second barrier structure on the base substrate.

In an exemplary embodiment, the drive structure layer includes a first semiconductor layer, a first gate insulation layer, a first conductive layer, a second gate insulation layer, a second conductive layer, an interlayer insulation layer, a third conductive layer, a planarization layer, and a fourth conductive layer that are sequentially stacked on the base substrate, and the second barrier structure is disposed in one or more of the first semiconductor layer, the first gate insulation layer, the first conductive layer, the second gate insulation layer, the second conductive layer, and the interlayer insulation layer.

In an exemplary embodiment, the groove structure and patterns on the first gate insulation layer, the second gate insulation layer, and the interlayer insulation layer are formed through a same patterning process.

In an exemplary embodiment, a strip-like convex structure and a film layer on which it is located are formed through a same patterning process.

In an exemplary embodiment, the second barrier structure includes at least one strip-like convex structure, or the second barrier structure includes at least one strip-like groove structure, or the second barrier structure includes at least one strip-like convex structure and at least one strip-like groove structure.

In an exemplary embodiment, in an extension direction of the second barrier structure, a plurality of convex structure segments are included in a same strip-like convex structure, and a convex spacing structure is disposed between two adjacent convex structure segments; a plurality of groove structure segments are included in a same strip-like groove structure, and a groove spacing structure is disposed between two adjacent groove structure segments.

In an exemplary embodiment, the second barrier structure includes a plurality of convex structures arranged in a direction perpendicular to the edge of the display area, wherein a plurality of convex structure segments of the plurality of convex structures are arranged in an array, or the plurality of convex structure segments of the plurality of convex structures are arranged in a staggered manner.

In an exemplary embodiment, in a same convex structure, a first included angle and a second included angle are formed between extension directions of two adjacent convex structure segments and an extension direction of the convex structure, respectively, and the first included angle and the second included angle are located on two sides of the extension direction of the convex structure.

In an exemplary embodiment, both the first included angle and the second included angle are less than or equal to 15 degrees.

In an exemplary embodiment, in the same convex structure, the plurality of convex structure segments includes a plurality of convex structure combinations, at least two interconnected convex structure segments are included in a same convex structure combination, and the two adjacent convex structure segments form a third included angle toward the display area or toward the first barrier structure.

In an exemplary embodiment, a spacing between two adjacent convex structures is between 0.4 microns to 5.5 microns; the convex structure has a width of 0.8 microns to 5.6 microns.

In an exemplary embodiment, the encapsulation structure layer includes a first encapsulation layer, a second encapsulation layer, and a third encapsulation layer, the first barrier structure being disposed to prevent a flow of the second encapsulation layer, and the second barrier structure being disposed to slow a flow rate of the second encapsulation layer.

In a second aspect, an embodiment of the present disclosure further provides a display device, including the display substrate according to any one of the embodiments described above.

In a third aspect, the embodiment of the present disclosure also provides a manufacturing method of a display substrate, wherein the display substrate includes a display area and a bezel area, and the bezel area is located at a periphery of the display area; in a direction perpendicular to a plane where the display substrate is located, the display substrate includes a base substrate and a light emitting device layer, an encapsulation structure layer sequentially stacked on the base substrate; the manufacturing method comprises:

forming a first barrier structure and a second barrier structure in the bezel area, wherein the first barrier structure is located between the light emitting device layer and the encapsulation structure layer, and the second barrier structure is located in the light emitting device layer.

Other aspects of the present disclosure may be comprehended after the drawings and the detailed descriptions are read and understood.

### BRIEF DESCRIPTION OF DRAWINGS

The accompanying drawings are intended to provide an understanding of technical solutions of embodiments of the present disclosure and form a part of the specification, and are used to explain the technical solutions of the present disclosure together with embodiments of the present disclosure, and not intended to form limitations on the technical solutions of the present disclosure. Shapes and sizes of each component in the drawings do not reflect actual scales, but are only intended to schematically illustrate contents of the present disclosure.

FIG. 1 is a schematic diagram of a structure of a display device.

FIG. 2 is a schematic diagram of a structure of a display substrate.

FIG. 3 is a schematic diagram of a planar structure of a display area in a display substrate.

FIG. 4 is a schematic diagram of cross-sectional structure of a display area in a display substrate.

FIG. 5 is a schematic diagram of an equivalent circuit of a pixel drive circuit.

FIG. 6 is a work timing diagram of a pixel drive circuit.

FIG. 7 is a schematic diagram of a planar structure of another display substrate according to an embodiment of the present disclosure.

FIG. 8a is a schematic diagram of a cross-sectional structure of a L1-L1 position in FIG. 7.

FIG. 8b is an enlarged schematic diagram of a structure at a position a1 in FIG. 7.

FIG. 8c is an enlarged schematic diagram of a structure at the position a1 in FIG. 7;

FIG. 8d is an enlarged schematic diagram of a structure at the position a1 in FIG. 7.

FIG. 8e is an enlarged schematic diagram of a structure at the position a1 in FIG. 7.

FIG. 8f is an enlarged schematic diagram of a structure at the position a1 in FIG. 7.

FIG. 8g is an enlarged schematic diagram of a structure at the position a1 in FIG. 7.

FIG. 8h is an enlarged schematic diagram of a structure at the position a1 in FIG. 7.

FIG. 8i is an enlarged schematic diagram of a structure at the position a1 in FIG. 7.

FIG. 8j is a schematic diagram of capillary effect between convex structures in an exemplary embodiment of the present disclosure.

FIG. 9a is a schematic diagram of a cross-sectional structure of the L1-L1 position in FIG. 7.

FIG. 9b is an enlarged schematic diagram of a structure at the position a1 in FIG. 7.

FIG. 10a is a schematic diagram of a cross-sectional structure of the L1-L1 position in FIG. 7.

FIG. 10b is an enlarged schematic diagram of a structure at the position a1 in FIG. 7.

FIG. 11a is a schematic diagram of a cross-sectional structure of the L1-L1 position in FIG. 7.

FIG. 11b is a schematic diagram of a cross-sectional structure of the L1-L1 position in FIG. 7.

FIG. 11c is a schematic diagram of a cross-sectional structure of the L1-L1 position in FIG. 7.

FIG. 11d is a schematic diagram of a cross-sectional structure of the L1-L1 position in FIG. 7.

FIG. 11e is a schematic diagram of a cross-sectional structure of the L1-L1 position in FIG. 7.

FIG. 11f is a schematic diagram of a cross-sectional structure of the L1-L1 position in FIG. 7.

FIG. 11g is a schematic diagram of a cross-sectional structure of the L1-L1 position in FIG. 7.

FIG. 11h is an enlarged schematic diagram of a structure at the position a1 in FIG. 7.

FIG. 11i is a schematic diagram of a cross-sectional structure of the L1-L1 position in FIG. 7.

FIG. 11j is an enlarged schematic diagram of a structure at the position a1 in FIG. 7.

FIG. 12a is a schematic diagram of a cross-sectional structure of a L2-L2 position in FIG. 7.

FIG. 12b is an enlarged schematic diagram of a structure at the position a1 in FIG. 7.

FIG. 12c is an enlarged schematic diagram of a structure at a position a2 in FIG. 7.

FIG. 13a is a schematic diagram of a cross-sectional structure of the L2-L2 position in FIG. 7.

FIG. 13b is a schematic diagram of a cross-sectional structure of the L1-L1 position in FIG. 7.

### DETAILED DESCRIPTION

The embodiments of the present disclosure will be described in detail below with reference to the accompanying drawings. Implementations may be implemented in a plurality of different forms. Those of ordinary skills in the art can easily understand such a fact that implementations and contents may be transformed into various forms without departing from the purpose and scope of embodiments of the present disclosure. Therefore, the embodiments of the present disclosure should not be explained as being limited to the contents recorded in the following implementations only. The embodiments in the present application and features in the embodiments may be combined with each other randomly if there is no conflict. In order to keep following description of the embodiments of the present disclosure clear and concise, detailed description of part of known functions and known components are omitted in the embodiments of the present disclosure. The drawings in the embodiments of the present disclosure relate only to the structures involved in the embodiments of the present disclosure, and other structures may be described with reference to conventional designs.

Scales of the drawings in embodiments of the present disclosure can be used as a reference in an actual process, but is not limited thereto. For example, a thickness and a pitch of each film layer, and a width and a pitch of each signal line may be adjusted according to an actual situation. The drawings described in the embodiments of the present disclosure are only schematic diagrams of structures, and one implementation of the embodiments of the present disclosure is not limited to shapes or numerical values or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction which is used for describing each constituent element. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification. In an embodiment of the present disclosure, the gate electrode may be referred to as a control electrode.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In an embodiment of the present disclosure, “about” refers to a value that is not strictly limited, a value within a range of process and measurement error is allowed.

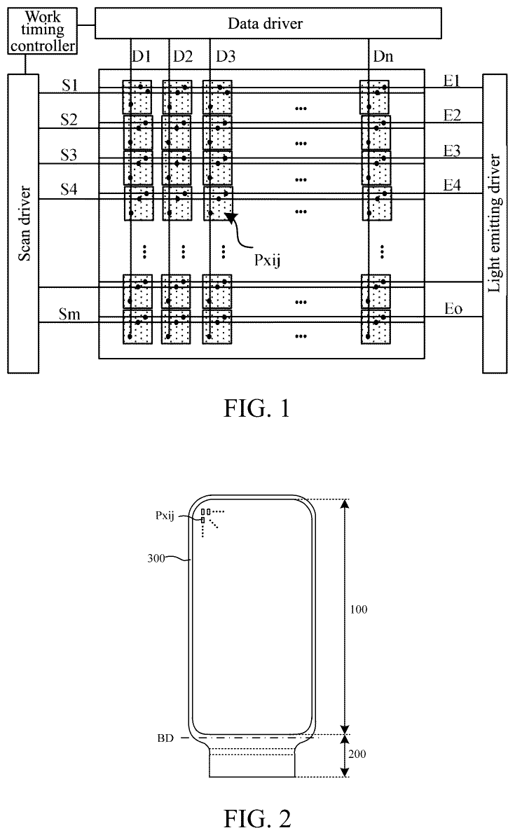

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive the clock signal, the emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display area 100, a bonding area 200 located on a side of the display area 100, and a bezel area 300 located on another side of the display area 100. In an exemplary implementation, the display area 100 may be a planar region including a plurality of sub-pixels Pxij that form a pixel array, the plurality of sub-pixels Pxij are configured to display a dynamic picture or a static image, and the display area 100 may be referred to as an Active Area (AA). In an exemplary implementation, the display substrate may be a flexible substrate, so that the display substrate may be deformable, for example, be curled, bent, folded, or rolled. In an exemplary implementation, the display substrate may further include a display area boundary BD, and the boundary BD may be an edge of the display area 100 at a side close to the bonding area 200.

In an exemplary implementation, the bonding region 200 may include a fanout region, a bending region, a drive chip region, and a bonding pin region disposed sequentially along a direction away from the display area. The fanout region is connected to the display area and includes multiple data fanout lines, and a data fanout line is configured to be connected to a data signal line (Data Line) of the display area in a Fanout routing manner. The fanout region occupies relatively large space, resulting in a relatively large width of a lower bezel. The bending region is connected to the fanout region and may include a composite insulation layer provided with a groove, and is configured to enable the bonding area to be bent to the back of the display area. The drive chip region may include an integrated circuit (IC for short) and is configured to be connected to the plurality of data fanout lines. The bonding pin region may include a bonding pad, and is configured to be connected to an external flexible printed circuit board (FPC for short) by bonding.

In an exemplary implementation, the bezel area 300 may include a circuit region, a power supply line region, and a crack dam region, and a cutting region which are sequentially arranged along the direction away from the display area. The circuit region is connected to the display area and may at least include a gate drive circuit, and the gate drive circuit is connected to a first scan signal line, a second scan signal line, a third scan signal line, and a light emitting control line of a pixel drive circuit in the display area. The power supply line region is connected to the circuit region and may at least include a power supply lead line. The power supply lead line extends along a direction parallel to an edge of the display area and is connected to a cathode in the display area. The crack dam region is connected to the power supply line region and may at least include a plurality of cracks provided on the composite insulation layer. The cutting region is connected to the crack dam region and may at least include a cutting groove arranged on the composite insulation layer, and the cutting groove is configured that a cutting equipment can cut along cutting grooves respectively after all film layers of the display substrate are manufactured.

In an exemplary implementation, the fanout region in the bonding area 200 and the power supply line region in the bezel area 300 may be provided with a first isolation dam and a second isolation dam. The first isolation dam and the second isolation dam may extend along the direction parallel to the edge of the display area, thus forming an annular structure surrounding the display area. The edge of the display area is an edge at a side of the display area, the bonding area, or the bezel area.

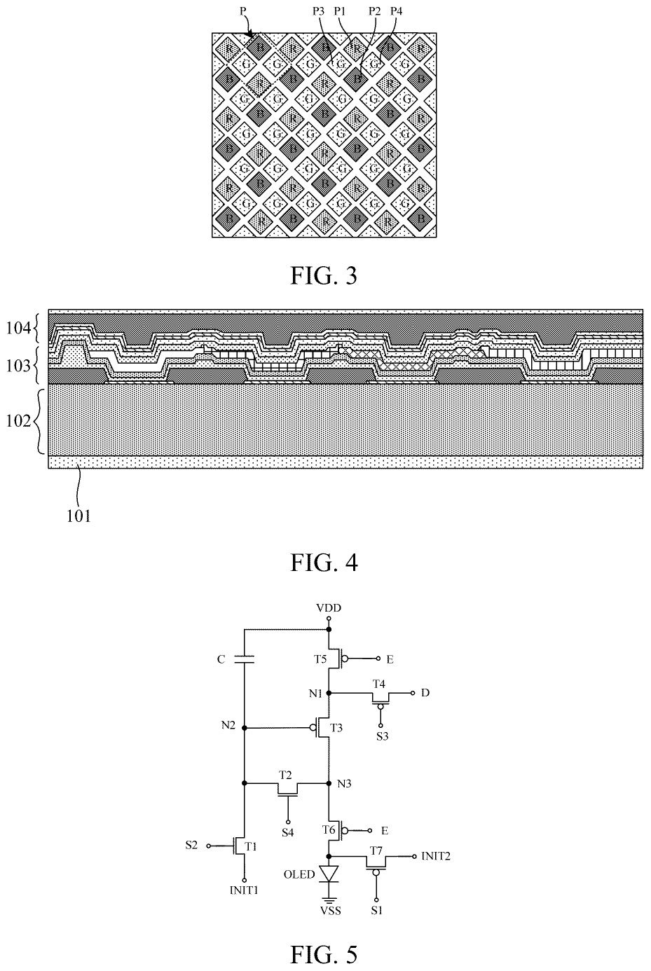

FIG. 3 is a schematic diagram of a planar structure of a display area in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 and a fourth sub-pixel P4 emitting light of a third color. Each sub-pixel may include a circuit unit and a light emitting element. The circuit unit may at least include a pixel drive circuit which is connected to a scan signal line, a data signal line, and a light emitting signal line respectively. The pixel drive circuit is configured to receive a data voltage transmitted by the data signal line and output a corresponding current to the light emitting element under control of the scan signal line and the light emitting signal line. The light emitting element in each sub-pixel is connected to a pixel drive circuit of a sub-pixel where the light emitting element is located, and is configured to emit light with corresponding brightness in response to a current output by the pixel drive circuit of the sub-pixel where the light emitting element is located.

In an exemplary implementation, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation, a sub-pixel may be in shape of a rectangle, a diamond, a pentagon, or a hexagon. The four sub-pixels may be arranged in a manner to form a diamond to form an RGBG pixel arrangement. In other exemplary implementations, the four sub-pixels may be arranged side by side horizontally, side by side vertically, or in a manner to form a square, which is not limited in the present disclosure.

In an exemplary implementation, a pixel unit may include three sub-pixels, and the three sub-pixels may be arranged side by side horizontally, side by side vertically, or in a delta-shaped arrangement, which is not limited here in the present disclosure.

FIG. 4 is a schematic diagram of cross-sectional structure of a display area in a display substrate, illustrating a structure of four sub-pixels in the display area. As shown in FIG. 4, on a plane perpendicular to the display substrate, the display substrate may include a drive circuit layer 102 disposed on a base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible substrate, or may be a rigid substrate. The drive circuit layer 102 of each sub-pixel may include a pixel drive circuit composed of a plurality of transistors and a storage capacitor. The light emitting structure layer 103 of each sub-pixel may include a light emitting element formed by a plurality of film layers, and the plurality of film layers may at least include an anode, a pixel definition layer, an organic light emitting layer, and a cathode. The anode is connected to the pixel drive circuit, the organic light emitting layer is connected to the anode, the cathode is connected to the organic light emitting layer, and the organic light emitting layer emits light of a corresponding color under drive of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

In an exemplary implementation, the organic light emitting layer may include an Emitting Layer (EML), and any one or more of the following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more of hole injection layers, hole transport layers, electron block layers, hole block layers, electron transport layers, and electron injection layers of all sub-pixels may be a common layer connected together. Emitting layers of adjacent sub-pixels may be overlapped slightly, or may be isolated from each other.

FIG. 5 is an equivalent circuit diagram of a pixel drive circuit. In an exemplary implementation, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7) and one storage capacitor C, and the pixel drive circuit is respectively connected to ten signal lines (a data signal line D, a first scan signal line S1, a second scan signal line S2, a third scan signal line S3, a fourth scan signal line S4, a light emitting signal line E, a first initial signal line INIT1, a second initial signal line INIT2, a first power supply line VDD, and a second power supply line VSS).

In an exemplary implementation, the pixel drive circuit may include a first node N1, a second node N2, and a third node N3. Among them, the first node N1 is respectively connected to a first electrode of the third transistor T3, a second electrode of the fourth transistor T4, and a second electrode of the fifth transistor T5, the second node N2 is respectively connected to a second electrode of the first transistor T1, a control electrode of the third transistor T3, and a second end of the storage capacitor C, and the third node N3 is respectively connected to a second electrode of the second transistor T2, a second electrode of the third transistor T3, and a first electrode of the sixth transistor T6.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

In an exemplary implementation, a control electrode of the first transistor T1 is connected to the second scan signal line S2, a first electrode of the first transistor T1 is connected to the first initial signal line INIT1, and the second electrode of the first transistor T1 is connected to the second node N2. When a turned-on scan signal is applied to the second scan signal line S2, the first transistor T1 transmits a first initialization voltage to the second end of the storage capacitor C to initialize the storage capacitor C.

In an exemplary implementation, a control electrode of the second transistor T2 is connected to the fourth scan signal line S4, a first electrode of the second transistor T2 is connected to the second electrode of the first transistor T1, and the second electrode of the second transistor T2 is connected to the third node N3. When a turned-on scan signal is applied to the fourth scan signal line S4, the second transistor T2 enables the control electrode of the third transistor T3 to be connected to the second electrode of the third transistor T3.

In an exemplary implementation, the control electrode of the third transistor T3 is connected to the second node N2, that is, the control electrode of the third transistor T3 is connected to the second end of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines a size of a drive current flowing between the first power supply line VDD and a light emitting element according to a potential difference between the control electrode and the first electrode of the third transistor T3.

In an exemplary implementation, a control electrode of the fourth transistor T4 is connected to the third scan signal line S3, a first electrode of the fourth transistor T4 is connected to the data signal line D, and the second electrode of the fourth transistor T4 is connected to the first node N1. When a turned-on scan signal is applied to the third scan signal line S3, the fourth transistor T4 enables a data voltage of the data signal line D to be input to the first node N1.

In an exemplary implementation, a control electrode of the fifth transistor T5 is connected to the light emitting signal line E, a first electrode of the fifth transistor T5 is connected to the first power supply line VDD, and the second electrode of the fifth transistor T5 is connected to the first node N1. A control electrode of the sixth transistor T6 is connected to the light emitting signal line E, the first electrode of the sixth transistor T6 is connected to the third node N3, and a second electrode of the sixth transistor T6 is connected to a first electrode of a light emitting element. When a turned-on light emitting signal is applied to the light emitting signal line E, the fifth transistor T5 and the sixth transistor T6 enable the light emitting element to emit light by forming a drive current path between the first power supply line VDD and the light emitting element.

In an exemplary implementation, a control electrode of the seventh transistor T7 is connected to the first scan signal line S1, a first electrode of the seventh transistor T7 is connected to the second initial signal line INIT2, and a second electrode of the seventh transistor T7 is connected to the first electrode of the light emitting element. When a turned-on scan signal is applied to the first scan signal line S1, the seventh transistor T7 transmits a second initial voltage to the first electrode of the light emitting device so as to initialize a charge amount accumulated in the first electrode of the light emitting element or release a charge amount accumulated in the first electrode of the light emitting element.

In an exemplary implementation, the light emitting element may be an OLED including a first electrode (anode), an organic light emitting layer, and a second electrode (cathode) which are stacked, or may be a QLED including a first electrode (anode), a quantum dot light emitting layer, and a second electrode (cathode) which are stacked.

In an exemplary embodiment, a second electrode of the emitting element is connected to the second power supply line VSS, a signal of the second power supply line VSS is a low level signal and a signal of the first power supply line VDD continuously provides a high-level signal.

In an exemplary implementation, the first transistor T1 to the seventh transistor T7 may be P-type transistors or N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first transistor T1 to the seventh transistor T7 may be low-temperature polysilicon transistors, or may be oxide transistors, or may be low-temperature polysilicon transistors and metal oxide transistors. Low Temperature Poly-Silicon (LTPS for short) is adopted for an active layer of a low temperature polysilicon transistor and a metal oxide semiconductor (Oxide) is adopted for an active layer of a metal oxide transistor. The low temperature polysilicon transistor has advantages such as a high migration rate and fast charging, and the oxide transistor has advantages such as a low drain current. The low temperature polysilicon transistor and the metal oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

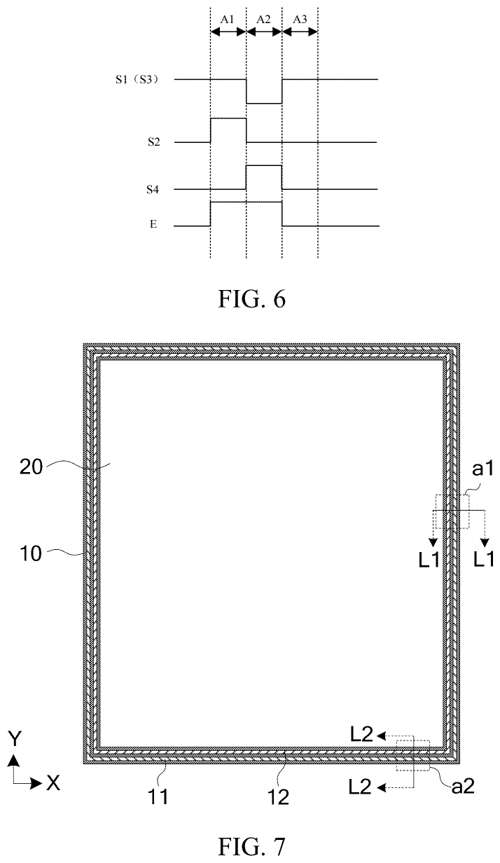

FIG. 6 is a work timing diagram of a pixel drive circuit. An exemplary embodiment of the present disclosure will be described below through a working process of the pixel drive circuit exemplified in FIG. 5. The pixel drive circuit in FIG. 5 includes seven transistors (a first transistor T1 to a seventh transistor T7) and one storage capacitor C, wherein the first transistor T1 and the second transistor T2 are N-type oxide transistors, and the third transistor T3 to the seven transistor T7 are P-type low-temperature polysilicon transistors. In an exemplary implementation, the working process of the pixel drive circuit may include following stages.

In a first stage A1, which is referred to as a reset stage, a signal of the second scan signal line S2 is a turned-on signal (high-level), and signals of the first scan signal line S1, the third scan signal line S3, the fourth scan signal line S4, and the light emitting signal line E are turned-off signals. The turned-on signal of the second scan signal line S2 enables the first transistor T1 to be turned on, and a signal of the first initial signal line INIT1 is provided to the second node N2 through the first transistor T1 to initialize (reset) the storage capacitor C, thereby clearing original charges in the storage capacitor. The turned-off signals of the first scan signal line S1, the third scan signal line S3, the fourth scan signal line S4, and the light emitting signal line E enable the second transistor T2, the fourth transistor T4, the fifth transistor T5, the sixth transistor T6, and the seventh transistor T7 to be turned off, and an OLED does not emit light in this stage.

In a second stage A2, referred to as a data writing stage or a threshold compensation stage, signals of the first scan signal line S1, the third scan signal line S3, and the fourth scan signal line S4 are turned-on signals, signals of the second scan signal line S2 and the light emitting signal line E are turned-off signals, and the data signal line D outputs a data voltage. In this stage, the second end of the storage capacitor C is at a low level, so the third transistor T3 is turned on. The turned-on signals of the first scan signal line S1, the third scan signal line S3, and the fourth scan signal line S4 enable the second transistor T2, the fourth transistor T4, and the seventh transistor T7 to be turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that a signal of the second initial signal line INIT2 is provided to a first electrode of the OLED to initialize (reset) the first electrode of the OLED and clear its internal pre-stored voltage, thereby completing initialization and ensuring that the OLED does not emit light. A turned-off signal of the second scan signal line S2 enables the first transistor T1 to be turned off, and a turned-off signal of the light emitting signal line E enables the fifth transistor T5 and the sixth transistor T6 to be turned off.

In a third stage A3, referred to as a light emitting stage, a signal of the light emitting signal line E is a turned-on signal, and signals of the first scan signal line S1, the second scan signal line S2, the third scan signal line S3, and the fourth scan signal line S4 are turned-off signals. The turned-on signal of the light emitting signal line E enables the fifth transistor T5 and the sixth transistor T6 to be turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. The voltage of the second node N2 is Vdata−|Vth|, so the drive current of the third transistor T3 is as follows:

$$I = K * {( Vgs - Vth )}^{2} = K * {[ ( Vdd - Vd + \vert Vth \vert ) - Vth ]}^{2} = K * {[ ( Vdd - Vd ) ]}^{2}$$

Herein, I is a drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

In a flexible encapsulation design, double barrier dams (Dam, which can be called isolation dams) to block Ink jet Print (abbreviated as IJP) is usually used, so as to prevent the IJP from crossing the Dam and causing water and oxygen intrusion, making the encapsulation invalid.

With the rapid development of OLED display technology, extremely narrow bezels are increasingly being pursued. In a process of narrowing the bezels, film layer structures of the bezels continue to shrink inward, which puts forward higher requirements for the flexible encapsulation. In related technologies, the design for the double barrier dams (Dam) used to block Ink jet Print (abbreviated as IJP) is difficult to meet the requirements for the extremely narrow bezels, such as undesirable problems including encapsulation air leakage, etc., Therefore, it is imminent to improve the encapsulation effect under the narrow bezels.

The embodiment of the present disclosure provides a display substrate, which may include a display area and a bezel area, wherein the bezel area is located at a periphery of the display area, and the bezel area is provided with a first barrier structure and a second barrier structure; in a direction perpendicular to a plane where the display substrate is located, the display substrate may include a base substrate and a drive structure layer, a light emitting structure layer, and an encapsulation structure layer sequentially stacked on the base substrate, wherein the first barrier structure may be disposed between the drive structure layer and the encapsulation structure layer, and the second barrier structure may be disposed in the drive structure layer.

The display substrate according to the embodiment of the present disclosure includes a display area and a bezel area, wherein the bezel area is provided with a first barrier structure and a second barrier structure; in a direction perpendicular to a plane where the display substrate is located, the display substrate include a base substrate and a drive structure layer, a light emitting structure layer, and an encapsulation structure layer sequentially stacked on the base substrate, wherein the first barrier structure is disposed between the drive structure layer and the encapsulation structure layer, and the second barrier structure is disposed in the drive structure layer. The combination of the second barrier structure and the first barrier structure greatly improves the encapsulation effect of the display substrate with the narrow bezels.

In an implementation of the present disclosure, the light emitting structure layer does not extend to the bezel area, and therefore, the first barrier structure may be disposed between the drive structure layer and the encapsulation structure layer. In other implementations of the present disclosure, the light emitting structure layer may extend to the bezel area and may extend to the region where the first barrier structure is located, and thus the first barrier structure may be disposed between the light emitting structure layer and the encapsulation structure layer.

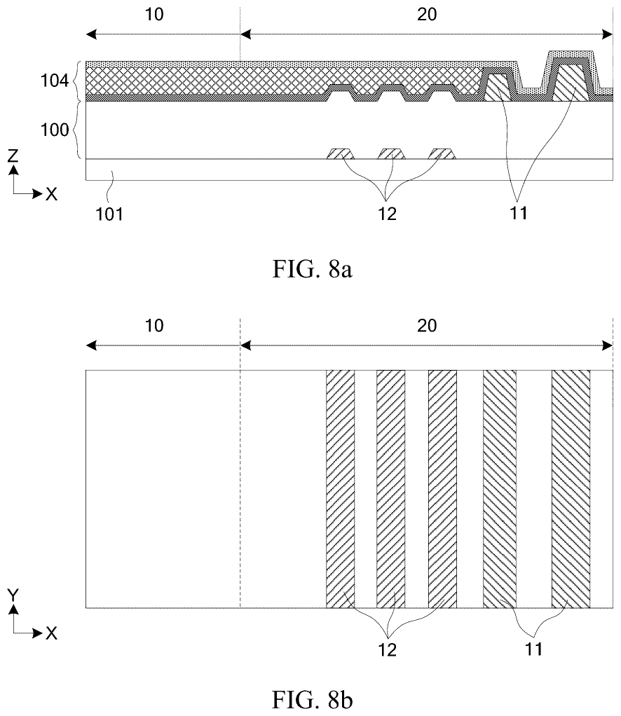

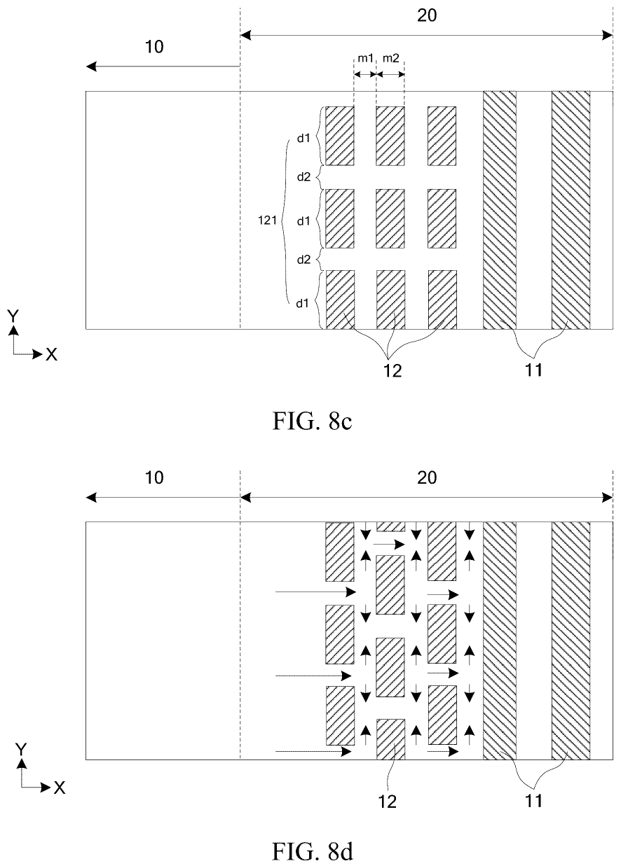

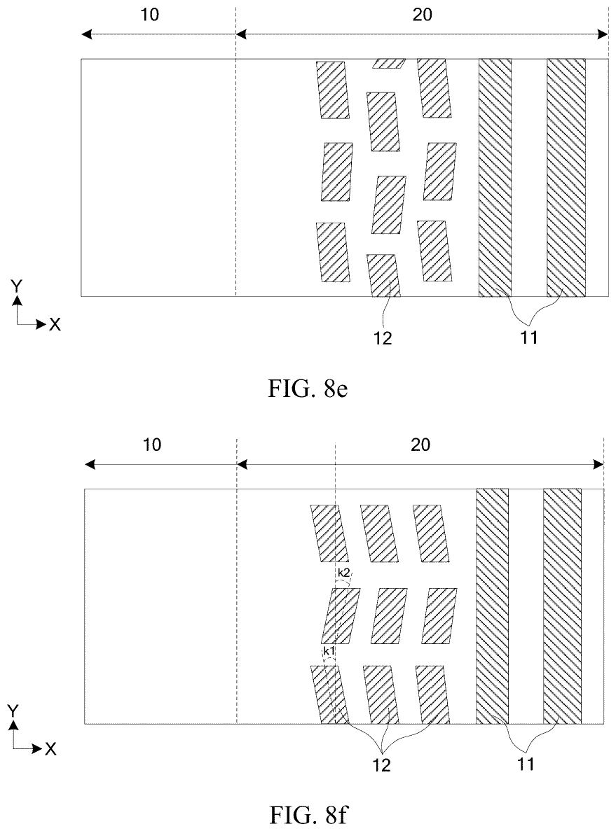

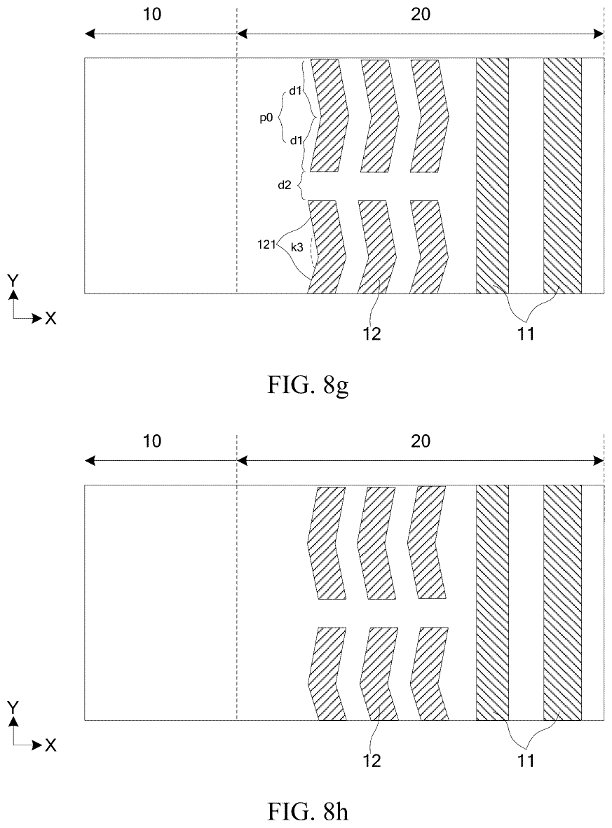

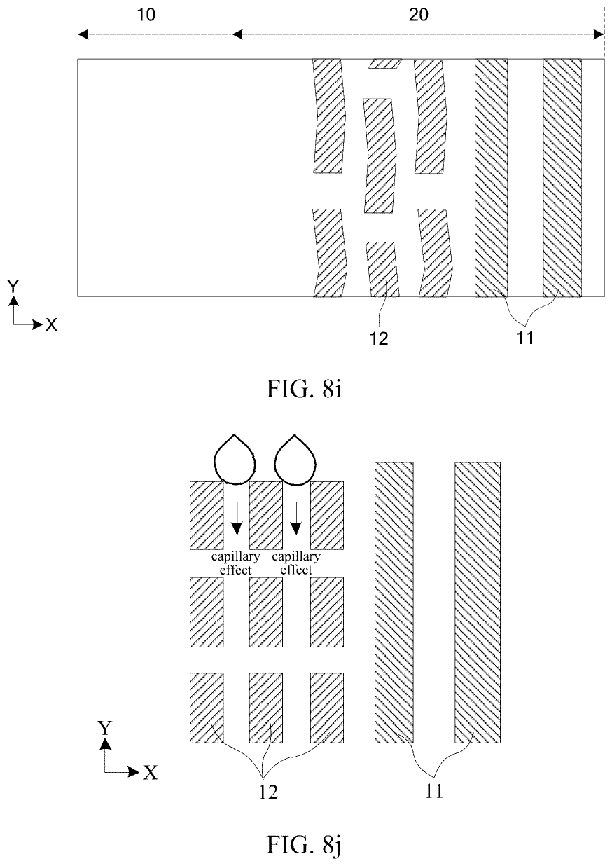

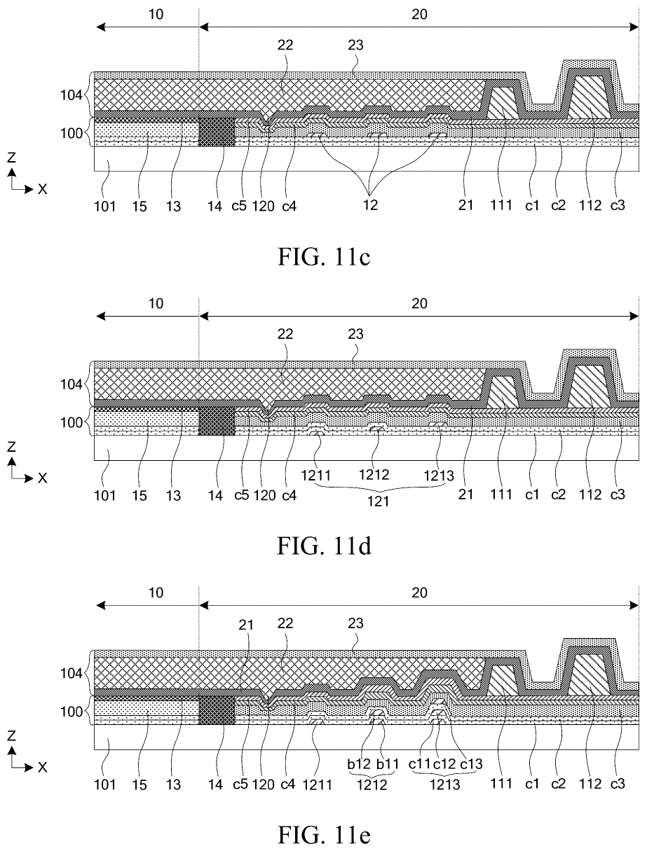

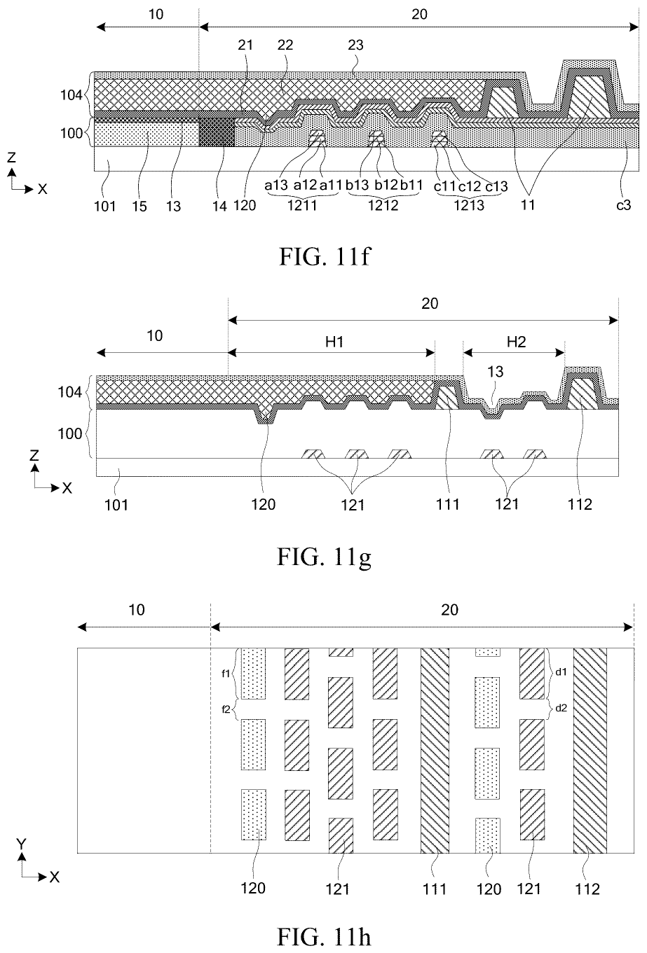

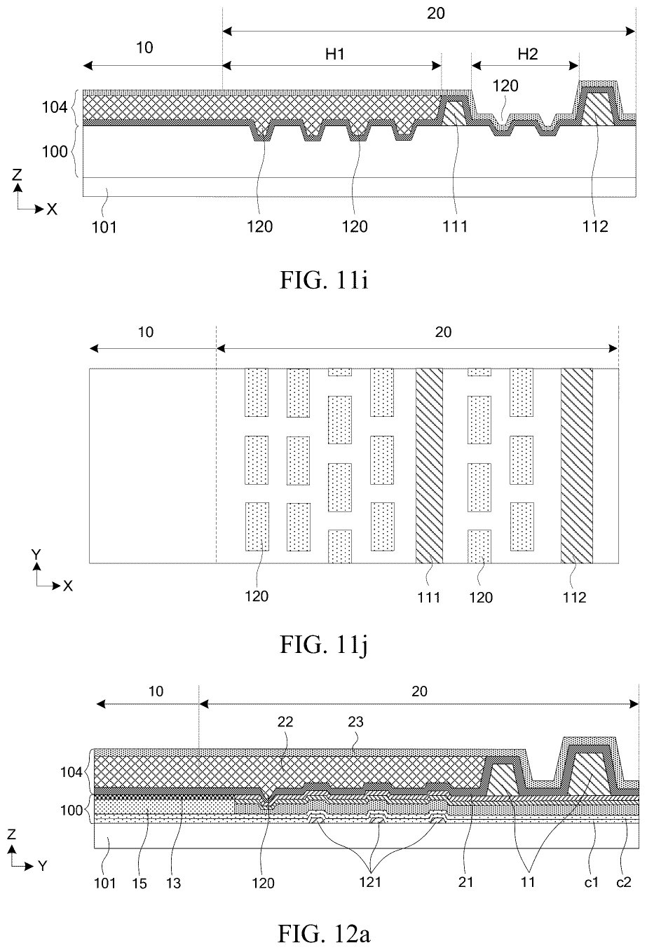

As shown in FIGS. 7 to 8i, FIG. 8a is a schematic diagram of a cross-sectional structure of a L1-L1 position in FIG. 7, and FIGS. 8b to 8i are enlarged schematic diagrams of a structure at a position a1 in FIG. 7. In a direction parallel to the plane where the display substrate is located, the display substrate may include a display area 10 and a bezel area 20, wherein the bezel area 20 is located at a periphery of the display area 10, and the bezel area 20 is provided with a first barrier structure 11 and a second barrier structure 12; in a direction Z perpendicular to the plane where the display substrate is located, the display substrate may include a base substrate 101 and a light emitting device layer 100, an encapsulation structure layer 104 sequentially stacked on the base substrate 101. The first barrier structure 11 may be disposed between the light emitting device layer 100 and the encapsulation structure layer 104, and the second barrier structure 12 may be disposed in the light emitting device layer 100. In an embodiment of the present disclosure, as shown in FIG. 11a, the light emitting device layer 100 may include a drive structure layer 102 and a light emitting structure layer 103 sequentially stacked on the base substrate 101. The second barrier structure 12 may be disposed in the drive structure layer 102 of the light emitting device layer 100. In an implementation of the present disclosure, the light emitting structure layer 103 may include, but is not limited to, a pixel defining layer 13. For example, the light emitting structure layer 103 may include at least an anode, a pixel defining layer, an organic light emitting layer and a cathode sequentially stacked on the drive structure layer 102, the anode being connected to a pixel driving circuit, the organic light emitting layer being connected to the anode, and the cathode being connected to the organic light emitting layer, and the organic light emitting layer emitting light of a corresponding color under the drive of the anode and the cathode. In an implementation of the present disclosure, the anode, the organic light emitting layer, and the cathode do not extend to the bezel area.

In an exemplary implementation, as shown in FIGS. 8b to 8i, the first barrier structure 11 and the second barrier structure 12 may both be in a strip shape, and extension directions of the first barrier structure 11 and the second barrier structure 12 may be consistent with extension directions of edges of the display area 10.

In an exemplary implementation, the extension directions of the first barrier structure 11 and the second barrier structure 12 may be a second direction Y.

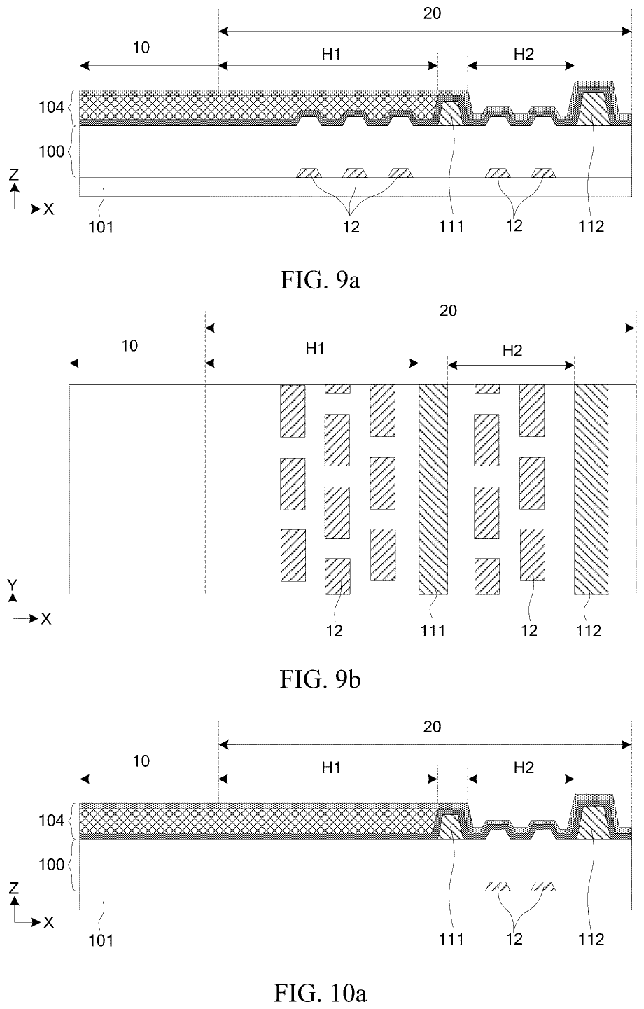

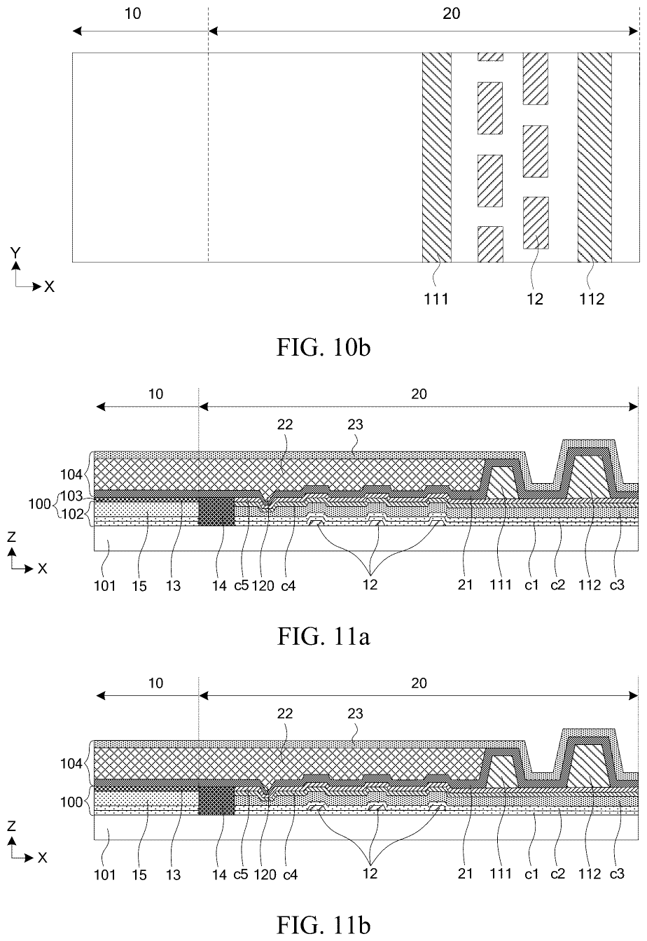

In an exemplary implementation, as shown in FIGS. 8a, 9a to 10b, FIGS. 8a, 9a, and 10a are three schematic diagrams of a cross-sectional structure of a position L1-L1 in FIG. 7, and FIGS. 9b and 10b are two enlarged schematic diagrams of a structure at the position a1 in FIG. 7. The first barrier structure 11 includes a first barrier dam 111 and a second barrier dam 112, and in a direction parallel to a plane where the display substrate is located, the bezel area 20 may include a first barrier area H1 and a second barrier area H2, the first barrier area H1 being located between the display area 10 and the first barrier dam 111, and the second barrier area H2 being located between the first barrier dam 111 and the second barrier dam 112; the second barrier structure 12 is disposed at at least one position in the first barrier area H1 and the second barrier area H2. As shown in FIG. 8a, the first barrier area H1 is provided with the second barrier structure 12, and as shown in FIG. 9a, both the first barrier area H1 and the second barrier area H2 are provided with the second barrier structure 12, and as shown in FIG. 10a, the second barrier area H2 is provided with the second barrier structure 12.

In the exemplary implementation, as shown in FIGS. 9a, 10a, and 11a, in a direction Z perpendicular to the plane where the display substrate is located, a size of the first barrier structure 11 is greater than or equal to a size of the second barrier structure 12, and a size of the second barrier dam 112 is greater than or equal to a size of the first barrier dam 111. In an exemplary implementation, in extension directions perpendicular to the edges of the display area, the size of the second barrier dam 112 is larger than or equal to the size of the first barrier dam 111.

In an exemplary implementation, as shown in FIGS. 11a to 11f, the encapsulation structure layer 104 may include a first encapsulation layer 21, a second encapsulation layer 22, and a third encapsulation layer 23, the first barrier structure 11 may be configured to prevent a flow of the second encapsulation layer 22, and the second barrier structure 12 may be configured to slow a flow rate of the second encapsulation layer 22.

In an exemplary implementation, the first encapsulation layer 21 and the third encapsulation layer 23 may be formed through Chemical Vapor Deposition (CVD). The second encapsulation layer 22 may be called Ink Jet Print (IJP), and the second encapsulation layer 22 has a certain flowability. The first barrier structure 11 is disposed in the bezel area 20 to block material in the second encapsulation layer 22 from flowing out of the bezel area 20. As shown in FIG. 11a, normally, the second encapsulation layer 22 does not exceed the first barrier dam 111 and the second barrier dam 112. The first barrier structure 11 can act as a barrier to external water vapor. As the bezel area is further narrowed, even if the first barrier structure is provided, there are still defects including encapsulation air leakage, etc., In an embodiment of the present disclosure, the second barrier structure 12 is added in a blank position of the bezel area 20, which improves the encapsulation effect under the narrow bezels. Among them, the strip-like convex structure 121 can act as a barrier to Ink Jet Print (that is, the second encapsulation layer 22), relieving a blocking pressure of the first barrier dam 111. A strip-like groove structure 120 can store a portion of the liquid of the Ink Jet Print, and can relieve the blocking pressure of the first barrier dam 111.

In an exemplary implementation, as shown in FIG. 11a, the drive structure layer 102 may include a first semiconductor layer, a first gate insulation layer c1, a first conductive layer, a second gate insulation layer c2, a second conductive layer, an interlayer insulation layer c3, a third conductive layer c4, a planarization layer 15, and a fourth conductive layer c5 that are sequentially stacked on the base substrate 101, and the second barrier structure 12 is disposed in one or more of the first semiconductor layer, the first conductive layer, and the second conductive layer.

In an exemplary implementation, as shown in FIGS. 11a to 11d, the second barrier structure 12 is a single-layer structure, and the second barrier structure 12 includes a plurality of strip-like convex structures 121, the plurality of strip-like convex structures 121 being disposed in one or more of the first semiconductor layer, the first conductive layer, and the second conductive layer; in the direction Z perpendicular to the plane where the display substrate is located, a size of any one of the convex structures 121 is consistent with a thickness of a film layer where it is located. As shown in FIGS. 11a to 11c, the plurality of strip-like convex structures 121 are disposed in one of the first semiconductor layer, the first conductive layer, and the second conductive layer. As shown in FIG. 11d, the plurality of strip-like convex structures 121 are disposed in a plurality of layers of the first semiconductor layer, the first conductive layer, and the second conductive layer.

In an exemplary implementation, the second barrier structure 12 may be a multilayer structure, and the second barrier structure 12 may include a plurality of strip-like convex structures 121, which may be disposed in a plurality of film layers of the first semiconductor layer, the first conductive layer, and the second conductive layer. As shown in FIGS. 11e and 11f.

In an exemplary implementation, in the direction Z perpendicular to the plane where the display substrate is located, the sizes of a plurality of strip-like convex structures 121 are consistent, any one convex structure 121 includes sub-convex structures 121 located in a plurality of film layers, and orthographic projections of the plurality of sub-convex structures 121 of a same convex structure 121 on the base substrate 101 are at least partially overlapped.

In an exemplary implementation, as shown in FIG. 11e, in any one of the first barrier area H1 and the second barrier area H2 and in a direction away from the display area 10, the sizes of the plurality of strip-like convex structures 121 are sequentially increased in the direction Z perpendicular to the plane where the display substrate is located, so that the plurality of convex structures 121 arranged in the direction perpendicular to the edge of the display area 10 are arranged in a stepped manner, and the encapsulation effect can be further improved. As shown in FIG. 11e, the plurality of convex structures 121 are arranged in the stepped manner, and the combination of the plurality of convex structures 121 with the groove structure increases a step drop, and the encapsulation effect can be further improved.

In an exemplary implementation, as shown in FIG. 11e, a second barrier structure 12 may include a first convex structure 1211, a second convex structure 1212, and a third convex structure 1213, the first convex structure 1211 being disposed in the first semiconductor layer, the second convex structure 1212 being disposed in the first semiconductor layer and the first conductive layer, and the third convex structure 1213 being disposed in the first semiconductor layer, the first conductive layer, and the second conductive layer.

In an exemplary implementation, as shown in FIG. 11e, the second convex structure 1212 may include two second sub-convex structures b11 and b12 located in the first semiconductor layer and the first conductive layer, respectively, and orthographic projections of the two second sub-convex structures b11 and b12 on the base substrate 101 are at least partially overlapped; the third convex structure 1213 includes three third sub-convex structures c11, c12, and c13 located in the first semiconductor layer, the first conductive layer, and the second conductive layer, respectively, and orthographic projections of the three third sub-convex structures c11 to c13 on the base substrate 101 are at least partially overlapped. In an embodiment of the present disclosure, the sizes of the first convex structure 1211, the second convex structure 1212, and the third convex structure 1213 are sequentially increased in the direction Z perpendicular to the plane where the display substrate is located, which is beneficial for improving the encapsulation effect.

In an exemplary implementation, as shown in FIGS. 11a to 11f, the second barrier structure 12 may further include at least one strip-like groove structure 120, which may be disposed in one or more of the first gate insulation layer c1, the second gate insulation layer c2, and the interlayer insulation layer c3. In an implementation of the present disclosure, the groove structure 120 and the convex structures 121 cooperate with each other to form a stepped elevated arrangement, which increases the drop between the groove structure 120 and the convex structures 121, and can be acted as a barrier to the Ink jet Print (i.e., the second encapsulation layer 22), thereby improving the encapsulation effect.

In an exemplary implementation, in the direction Z parallel to the plane where the display substrate is located, and in the first barrier area H1, the groove structure 120 may be located between the display area 10 and the convex structures 121, as shown in FIGS. 11a to 11f; in the second barrier area H2, the groove structure 120 may be located between the first barrier dam 111 and the convex structures 121, as shown in FIGS. 11g and 11h. Among them, FIGS. 11a to 11g are schematic diagrams of a cross-sectional structure of the L1-L1 position in FIG. 7, and FIG. 11h is an enlarged schematic diagram of a structure at the position a1 in FIG. 7.

In an exemplary implementation, as shown in FIG. 11e, in any one of the first barrier area H1 and the second barrier area H2, and in the direction Z perpendicular to the plane where the display substrate is located, heights of the surfaces of the groove structure 120 and the convex structures 121 in the second barrier structure 12 on a side away from the base substrate 101 are sequentially increased with respect to the base substrate 101. As shown in FIG. 11e, in the first barrier area H1, and in the direction Z perpendicular to the plane where the display substrate is located, the heights of the surfaces of the groove structure 120 and the convex structures 121 in the second barrier structure 12 on the side away from the base substrate 101 are sequentially increased with respect to the base substrate 101. As shown in FIG. 11g, in the second barrier area H2, and in the direction Z perpendicular to the plane where the display substrate is located, the heights of the surfaces of the groove structure 120 and the convex structures 121 in the second barrier structure 12 on the side away from the base substrate 101 are sequentially increased with respect to the base substrate 101.

In an exemplary implementation, as shown in FIG. 11a, at least one of the third conductive layer c4 and the fourth conductive layer c5 extends to the bezel area 20 in a direction Z parallel to the plane where the display substrate is located, at least one of the third conductive layer c4 and the fourth conductive layer c5 is provided with a second power supply line, and an orthographic projection of the second barrier structure 12 on the base substrate 101 has an overlapping area with an orthographic projection of the second power supply line on the base substrate 101.

In an exemplary implementation, in the bezel area 20, a cross-sectional shape of the a region where the orthographic projections of the third conductive layer c4, the fourth conductive layer c5 and the second barrier structure 12 are overlapped on the base substrate 101 is consistent with a cross-sectional shape of the second barrier structure 12, and the third conductive layer c4, the fourth conductive layer c5 inherits the second barrier structure 12 in morphology, so that a corresponding protrusion or groove shape can be formed in the second encapsulation layer 22 of the encapsulation layer 104, so as to achieve blocking of the liquid in the second encapsulation layer 22, reduce a blocking pressure of the first barrier structure 11, and improve the encapsulation effect. As shown in FIG. 11e, the third conductive layer c4 and the fourth conductive layer c5 exhibit a groove morphology at the position of the groove structure 120 and a convex morphology at the position of the convex structures 1211, 1212, and 1213.

In an exemplary implementation, the bezel area 20 is provided with a GOA circuit 14, and an orthographic projection of the GOA circuit 14 on the base substrate 101 is not overlapped with an orthographic projection of the second barrier structure 12 on the base substrate 101.

In an exemplary implementation, the drive structure layer 102 may include a first semiconductor layer, a first gate insulation layer c1, a first conductive layer, a second gate insulation layer c2, a second conductive layer, an interlayer insulation layer c3, a third conductive layer c4, a planarization layer 15, and a fourth conductive layer c5 that are sequentially stacked on the base substrate 101, and the second barrier structure 12 may be disposed in one or more of the first semiconductor layer, the first gate insulation layer c1, the first conductive layer, the second gate insulation layer c2, the second conductive layer, and the interlayer insulation layer 15. As shown in FIG. 11e, convex structures 121 are disposed in the first semiconductor layer, the first conductive layer, and the second conductive layer of the drive structure layer 102, and a groove structure 120 is disposed in the planarization layer 15. In an implementation of the present disclosure, the first semiconductor layer, the first conductive layer, and the second conductive layer in the drive structure layer 102 do not extend to the bezel area 20, and the convex structures 121 located in the bezel area may be formed with one or more layers of the first semiconductor layer, the first conductive layer, and the second conductive layer in the drive structure layer 102 through a same patterning process, so that the number of uses of a mask plate for patterning is reduced, and thus there is no need to manufacture the second barrier structure 12 separately using a mask board, and a pattern of the second barrier structure 12 may be added to the mask plate for manufacturing one or more layers of the first semiconductor layer, the first conductive layer, and the second conductive layer, which greatly reduces the cost of manufacturing the display substrate.

In an exemplary implementation, the groove structure 120 may be formed through a same patterning process with the patterns on the first gate insulation layer c1, the second gate insulation layer c2, and the interlayer insulation layer c3. For example, as shown in FIGS. 11a to 11f, the groove structure 120 may be formed through a same patterning process with a pattern on the interlayer insulation layer c3. In an embodiment of the present disclosure, the groove structure 120 and original film layers in the display substrate are formed through a same patterning process, without a need for separate manufacturing, which saves the cost of manufacturing the display substrate.

In an exemplary implementation, the strip-like convex structure 121 may be formed with the film layer where it is located through a same patterning process. As shown in FIGS. 11a to 11f, the strip-like convex structures 121 and the original film layers in the display substrate are formed through a same patterning process, without a need for manufacturing the convex structures 121 separately, which saves the process of manufacturing the display substrate and reduces the cost of manufacturing the display substrate. As shown in FIG. 11a, the strip-like convex structures 121 are single-layer structures and formed with the first semiconductor layer through a same patterning process; as shown in FIG. 11b, the strip-like convex structures 121 are single-layer structures and formed with the first conductive layer through a same patterning process; as shown in FIG. 11c, the strip-like convex structures 121 are single-layer structures and formed with the second conductive layer through a same patterning process; as shown in FIG. 11d, the strip-like convex structures 121 are single-layer structures and formed with the second conductive layer through a same patterning process; as shown in FIG. 11e, the strip-like convex structures 121 may include a first convex structure 1211, a second convex structure 1212, and a third convex structure 1213, wherein the first convex structure 1211 is a single-layer structure and formed with the first semiconductor layer through a same patterning process, the second convex structure 1212 is a multi-layer structure including two second sub-convex structures b11 and b12, the second sub-convex structure b11 is formed with the first semiconductor layer through a same patterning process, the second sub-convex structure b12 is formed with the first conductive layer through a same patterning process, the third convex structure 1213 includes three third sub-convex structures c11 to c13, the third sub-convex structure c11 is formed with the first semiconductor layer through a same patterning process, the third sub-convex structure c12 is formed with the first conductive layer through a same patterning process, and the third sub-convex structure c13 is formed with the second conductive layer through a same patterning process.

In an exemplary implementation, as shown in FIGS. 8a to 10b, the second barrier structure 12 may include at least one strip-like convex structure 121 or, as shown in FIGS. 11i to 11j, the second barrier structure 12 may include at least one strip-like convex structure 121, or, as shown in FIGS. 11a to 11h, the second barrier structure 12 may include at least one strip-like convex structure 121 and at least one striped groove structure 120.

In an embodiment of the present disclosure, the strip-like convex structures 121 can be acted as a barrier to the second encapsulation layer 22 and reduce the blocking pressure of the first barrier dam 111. The groove structure 120 can store a part of the liquid in the second encapsulation layer 22, and can reduce the flow rate of the liquid in the second encapsulation layer 22, and can reduce the blocking pressure of the first barrier dam 111 to a certain extent. That is, both the convex structures 121 and the groove structure 120 can reduce the blocking pressure of the first barrier dam 111, and improve the encapsulation effect of the narrow bezels. The way in which the groove structure 120 and the convex structure 121 cooperate can further improve the encapsulation effect. The groove structure 120 or the convex structures 121 disposed in the first barrier area H1 can reduce the blocking pressure of the first barrier dam 111, the groove structure 120 or the convex structures 121 disposed in the second barrier area H2 can reduce the blocking pressure of the second barrier dam 112. The groove structure 120 and the convex structures 121 are disposed in both the first barrier area H1 and the second barrier area H2.

In an exemplary implementation, as shown in FIGS. 8c and 11h, in an extension direction of the second barrier structure 12, a plurality of convex structure d1 segments may be included in a same strip-like convex structure 121, and a convex spacing structure d2 is disposed between the two adjacent convex structure 121 segments.

In an exemplary implementation, as shown in FIG. 11h, a same strip-like groove structure 120 may include a plurality of groove structure segments f1, and a groove spacing structure f2 is disposed between the two adjacent groove structure f1.

In an exemplary implementation, the second barrier structure 12 includes a plurality of convex structures 121 arranged in directions perpendicular to the edges of the display area 10, wherein the plurality of convex structure segments d1 of the plurality of convex structures 121 are arranged in an array, or the plurality of convex structure segments d1 of the plurality of convex structures 121 are arranged in a staggered manner.

As shown in FIG. 8d, a plurality of convex structure segments d1 of the plurality of convex structures 121 are arranged in a staggered manner, and a flow path of the liquid in the second encapsulation layer 22 is in directions of arrows in FIG. 8d. Two adjacent convex structure segments are in a same convex structure 121. After the liquid flows in from the convex spacing structure d2 between any two adjacent convex structure segments d1, the liquid will be blocked by the next convex structure 121, and the flow direction of the liquid is changed to flow in two directions parallel to the first barrier dam 111, so that the liquid will be blocked by the different convex structures 121, which increases the path of the liquid flow, and improves the encapsulation effect of the narrow bezels.

In an exemplary implementation, as shown in FIG. 8f, in a same convex structure 121, a first included angle k1 and a second included angle k2 are formed between extension directions of the two adjacent convex structure segments d1 and an extension direction of the convex structure 121, respectively, and the first included angle k1 and the second included angle k2 are located on two sides of the extension direction of the convex structure 121. For example, in FIG. 8f, the extension direction of the convex structure 121 may be in Y. In an exemplary implementation, the first included angle k1 and the second included angle k2 may be equal.

In an exemplary implementation, both the first included angle k1 and the second included angle k2 are less than or equal to 15 degrees.

In an exemplary implementation, as shown in FIGS. 8e to 8i, in a same convex structure 121, a plurality of convex structure 121 segments include a plurality of convex structure combinations p0, at least two interconnected convex structure segments d1 are included in a same convex structure combination p0, and the two adjacent convex structure segments d1 form a third included angle k3 toward the display area 10 or toward the first barrier structure 11. In an exemplary implementation, the third included angle k3 may be an obtuse angle. In a same combination p0, in a direction in which the liquid flows in the second encapsulation layer 22 perpendicular to the display area 10, one combination p0 as a whole can block the liquid, slow down the flow rate of the liquid, and thus improve the encapsulation effect of the bezels.

In an exemplary implementation, as shown in FIG. 8c, a spacing m1 between the two adjacent convex structures 121 is between 0.4 microns to 5.5 microns. For example, the spacing m1 between the two adjacent convex structures 121 is between 0.4 microns to 4.8 microns. A width m2 of the convex structure 121 is between 0.8 microns to 5.6 microns. For example, the width m2 of the convex structure 121 is 5 microns.

In an embodiment of the present disclosure, the spacing between the two adjacent convex structures 121 (i.e., a distance between the two adjacent convex structures 121 in a first direction X in FIG. 8c) is as small as possible while ensuring the process yield. As shown in FIG. 8j, in a case that the liquid in the second encapsulation layer 22 flows to the gap between the adjacent two convex structures 121, a capillary phenomenon (i.e., capillary effect) is generated because the distance between the two adjacent convex structures 121 is small enough, so that the liquid is blocked, and the blocking pressure of the first barrier structure 11 is reduced to a certain extent.

In an embodiment of the present disclosure, in order to dispose more convex structures 121 between the display area 10 and the first barrier structure 11, the width m2 of the convex structures 121 is as small as possible while ensuring the process yield, so as to increase the number of the convex structures 121, thereby improving the blocking effect. In an embodiment of the present disclosure, a size of the barrier structure segment d1 in an extension direction of the display area 10 is as large as possible to improve the blocking effect on the liquid in the second encapsulation layer 22.

In an exemplary implementation, as shown in FIGS. 8d and 9b, the capillary effect is combined with the staggered arrangement between the convex structure segments d1, and the superposition of the two blocking effects can further improve the blocking of the liquid in the second encapsulation layer 22, so that the encapsulation effect of the narrow bezels can be further improved.

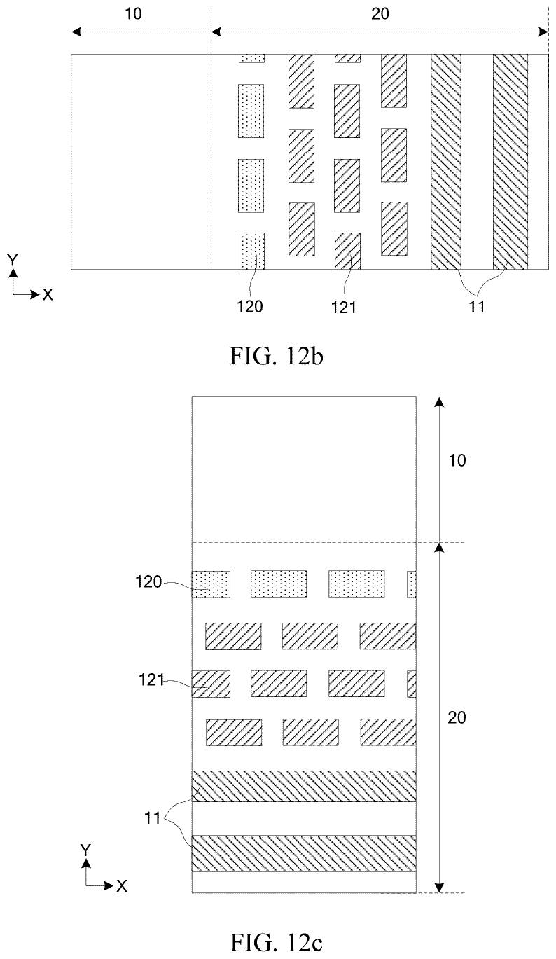

In an exemplary implementation, as shown in FIG. 7, the display substrate may include an upper bezel, a lower bezel, a left bezel, and a right bezel, extension directions of the upper and lower bezels being consistent (e.g., both extending in a first direction X), and extension directions of the left bezel and the right bezel being consistent (e.g., both extending in a second direction Y). In an exemplary implementation, as shown, FIG. 11a is a schematic diagram of a cross-sectional structure of a L1-L1 position in FIG. 7, and FIG. 12a is a schematic diagram of a cross-sectional structure of a L2-L2 position in FIG. 7. As shown in FIG. 11a, a Gate Driver on Array (GOA) circuit 14 is disposed on the left and right bezels of the display substrate, and the GOA circuit 14 is located between the display area 10 and the second barrier structure 12. The display area 10 is provided with a first gate insulation layer c1, a second gate insulation layer c2, a planarization layer 15, and a pixel definition layer 13. The second barrier structure 12 is disposed between the GOA circuit 14 and the first barrier dam 111. As shown in FIG. 12a, at the positions of the upper and lower bezels of the display substrate, the second barrier structure 12 is disposed between the display area and the second barrier structure 12. As shown in FIG. 12b, it is an enlarged schematic diagram of a structure at the position a1 in FIG. 7, and FIG. 12c is an enlarged schematic diagram of a structure at a position a2 in FIG. 7. In an exemplary implementation, both ends of the upper bezel in the display substrate are respectively connected to one end of the left and right bezels, and both ends of the lower bezels are respectively connected to the other ends of the left and right bezels.

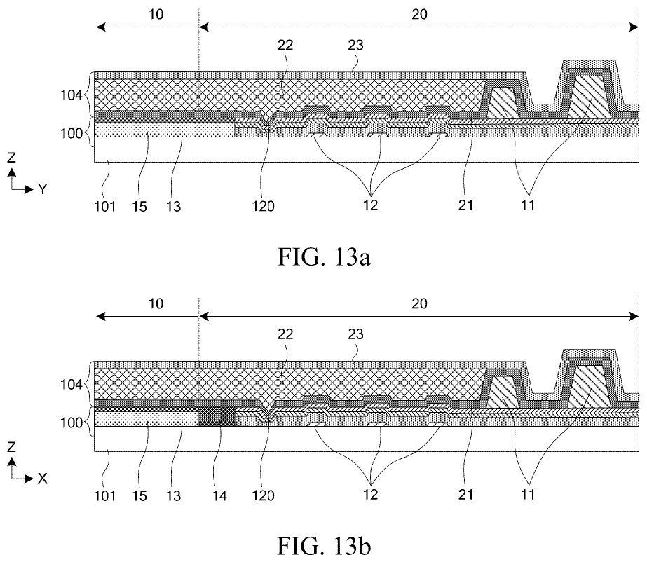

In an exemplary implementation, the light emitting device layer 100 may include a drive structure layer and a light emitting structure layer sequentially stacked on the base substrate 101. The first gate insulation layer c1, the first conductive layer, and the second gate insulation layer c2 in the drive structure layer is disposed in the display area 10 and not disposed in the bezel area 20. As shown in FIGS. 13a and 13b, FIG. 13a is a schematic diagram of a cross-sectional structure of the L2-L2 position in FIG. 7, and FIG. 13b is a schematic diagram of a cross-sectional structure of the L1-L1 position in FIG. 7. In other exemplary implementations, the first gate insulation layer c1 and the second gate insulation layer c2 in the drive structure layer extend to the bezel area 20, as shown in FIGS. 11a to 11e.

An embodiment of the present disclosure further provides a display device, which may include the display substrate described in any one of the aforementioned embodiments. In an exemplary implementation, the display device may be any product or component with a display function, such as a mobile phone, a tablet computer, a television, a display, a laptop, a digital photo frame, or a navigator.

The embodiment of the present disclosure also provides a manufacturing method of a display substrate, wherein the display substrate may include a display area and a bezel area, and the bezel area is located at a periphery of the display area; in a direction perpendicular to the plane where the display substrate is located, the display substrate may include a substrate and a light emitting device layer, an encapsulation structure layer sequentially stacked on the base substrate; the manufacturing method may comprise:
forming a first barrier structure and a second barrier structure in the bezel area, wherein the first barrier structure is located between the light emitting device layer and the encapsulation structure layer, and the second barrier structure is located in the light emitting device layer.

An embodiment of the present disclosure provides a display substrate and a display device. The display substrate include a display area and a bezel area, wherein the bezel area is provided with a first barrier structure and a second barrier structure; in a direction perpendicular to a plane where the display substrate is located, the display substrate include a base substrate and a drive structure layer, a light emitting structure layer, and an encapsulation structure layer sequentially stacked on the base substrate, wherein the first barrier structure is disposed between the drive structure layer and the encapsulation structure layer, and the second barrier structure is disposed at the drive structure layer. The combination of the second barrier structure and the first barrier structure greatly improves the encapsulation effect of the display substrate with the narrow bezels.

The drawings of the embodiments of the present disclosure only involve structures involved in the embodiments of the present disclosure, and other structures may refer to a general design.

The embodiments of the present disclosure, that is, features in the embodiments, may be combined with each other to obtain a new embodiment in a situation of no conflicts.

Although the implementations disclosed in the embodiments of the present disclosure are described above, the described contents are only implementations used for facilitating understanding of the embodiments of the present disclosure, but are not intended to limit the embodiments of the present disclosure. Any person skilled in the art to which the embodiments of the present disclosure pertain may make any modifications and variations in forms and details of implementation without departing from the spirit and the scope disclosed in the embodiments of the present disclosure. Nevertheless, the scope of patent protection of the embodiments of the present disclosure shall still be subject to the scope defined by the appended claims.

1. A display substrate, comprising a display area and a bezel area, wherein the bezel area is located at a periphery of the display area, and the bezel area is provided with a first barrier structure and a second barrier structure; in a direction perpendicular to a plane where the display substrate is located, the display substrate comprises a base substrate and a drive structure layer, a light emitting structure layer, and an encapsulation structure layer sequentially stacked on the base substrate, wherein the first barrier structure is disposed between the drive structure layer and the encapsulation structure layer, and the second barrier structure is disposed in the drive structure layer.

2. The display substrate according to claim 1, wherein each of the first barrier structure and the second barrier structure is in a strip shape, and extension directions of the first barrier structure and the second barrier structure are consistent with an extension direction of an edge of the display area.

3. The display substrate according to claim 2, wherein the first barrier structure comprises a first barrier dam and a second barrier dam, and in a direction parallel to the plane where the display substrate is located, the bezel area comprises a first barrier area and a second barrier area, the first barrier area is located between the display area and the first barrier dam, and the second barrier area is located between the first barrier dam and the second barrier dam; and the second barrier structure is disposed at, at least one position in the first barrier area and the second barrier area.

4. The display substrate according to claim 3, wherein in the direction perpendicular to the plane where the display substrate is located, a size of the first barrier structure is greater than or equal to a size of the second barrier structure, and a size of the second barrier dam is greater than or equal to a size of the first barrier dam; in an extension direction perpendicular to the edge of the display area, a size of the second barrier dam is greater than or equal to a size of the first barrier dam.

5. The display substrate according to claim 3, wherein the drive structure layer comprises a first semiconductor layer, a first gate insulation layer, a first conductive layer, a second gate insulation layer, a second conductive layer, an interlayer insulation layer, a third conductive layer, a planarization layer, and a fourth conductive layer that are sequentially stacked on the base substrate, and the second barrier structure is disposed in one or more of the first semiconductor layer, the first conductive layer, and the second conductive layer.

6. The display substrate according to claim 5, wherein the second barrier structure is a single-layer structure, the second barrier structure comprises a plurality of strip-like convex structures, the plurality of strip-like convex structures are disposed in one or more of the first semiconductor layer, the first conductive layer, and the second conductive layer; in the direction perpendicular to the plane where the display substrate is located, a size of any one of the convex structures is consistent with a thickness of a film layer on which the convex structure is located; or
wherein the second barrier structure is a multilayer structure, and the second barrier structure comprises a plurality of strip-like convex structures disposed in a plurality of film layers of the first semiconductor layer, the first conductive layer, and the second conductive layer.

7. (canceled)

8. The display substrate according to claim 6, wherein in the direction perpendicular to the plane where the display substrate is located, sizes of the plurality of strip-like convex structures are consistent with each other, any one of the convex structures comprises sub-convex structures located in the plurality of film layers, and orthographic projections of the plurality of sub-convex structures in a same convex structure on the base substrate are at least partially overlapped; or
wherein in a direction away from the display area, and in any one of the first barrier area and the second barrier area, sizes of the plurality of strip-like convex structures are sequentially increased in the direction perpendicular to the plane where the display substrate is located.

9. (canceled)

10. The display substrate according to claim 8, wherein the second barrier structure comprises a first convex structure disposed in the first semiconductor layer, a second convex structure disposed in the first semiconductor layer and the first conductive layer, and a third convex structure disposed in the first semiconductor layer, the first conductive layer and the second conductive layer.

11. The display substrate according to claim 10, wherein the second convex structure comprises two second sub-convex structures located in the first semiconductor layer and the first conductive layer respectively, and orthographic projections of the two second sub-convex structures on the base substrate are at least partially overlapped; the third convex structure comprises three third sub-convex structures located in the first semiconductor layer, the first conductive layer, and the second conductive layer, respectively, and orthographic projections of the three third sub-convex structures on the base substrate are at least partially overlapped.

12. The display substrate according to claim 6, wherein the second barrier structure further comprises at least one strip-like groove structure disposed in one or more of the first gate insulation layer, the second gate insulation layer, and the interlayer insulation layer.

13. The display substrate according to claim 12, wherein in the direction parallel to the plane where the display substrate is located, and in the first barrier area, the at least one groove structure is located between the display area and the convex structures; in the second barrier area, the at least one groove structure is located between the first barrier dam and the convex structures.

14. The display substrate according to claim 13, wherein in any one of the first barrier area and the second barrier area, and in the direction perpendicular to the plane where the display substrate is located, heights of surfaces of the at least one groove structure and the convex structures in the second barrier structure on a side away from the base substrate are sequentially increased with respect to the base substrate.

15. The display substrate according to claim 5, wherein at least one of the third conductive layer and the fourth conductive layer extends to the bezel area in the direction parallel to the plane where the display substrate is located, at least one of the third conductive layer and the fourth conductive layer is provided with a second power supply line, and an orthographic projection of the second barrier structure on the base substrate is at least partially overlapped with an orthographic projection of the second power supply line on the base substrate.

16. The display substrate according to claim 15, wherein in the bezel area, a cross-sectional shape of an overlapping region between orthographic projections of the third conductive layer, the fourth conductive layer and the second barrier structure on the base substrate is consistent with a cross-sectional shape of the second barrier structure.

17. The display substrate according to claim 1, wherein the bezel area is provided with a date driver on array (GOA) circuit, and an orthographic projection of the GOA circuit on the base substrate is not overlapped with an orthographic projection of the second barrier structure on the base substrate; or
wherein the drive structure layer comprises a first semiconductor layer, a first gate insulation layer, a first conductive layer, a second gate insulation layer, a second conductive layer, an interlayer insulation layer, a third conductive layer, a planarization layer, and a fourth conductive layer that are sequentially stacked on the base substrate, and the second barrier structure is disposed in one or more of the first semiconductor layer, the first gate insulation layer, the first conductive layer, the second gate insulation layer, the second conductive layer, and the interlayer insulation layer.

18. (canceled)

19. The display substrate according to claim 2, wherein the second barrier structure comprises at least one strip-like convex structure, or the second barrier structure comprises at least one strip-like groove structure, or the second barrier structure comprises at least one strip-like convex structure and at least one strip-like groove structure.

20. The display substrate according to claim 19, wherein in an extension direction of the second barrier structure, a plurality of convex structure segments are comprised in a same strip-like convex structure, and a convex spacing structure is disposed between two adjacent convex structure segments; a plurality of groove structure segments are comprised in a same strip-like groove structure, and a groove spacing structure is disposed between two adjacent groove structure segments.

21. The display substrate according to claim 20, wherein the second barrier structure comprises a plurality of convex structures arranged in a direction perpendicular to the edge of the display area, wherein a plurality of convex structure segments of the plurality of convex structures are arranged in an array, or the plurality of convex structure segments of the plurality of convex structures are arranged in a staggered manner; and
wherein in a same convex structure, a first included angle and a second included angle are formed between extension directions of two adjacent convex structure segments and an extension direction of the convex structure, respectively, and the first included angle and the second included angle are located on two sides of the extension direction of the convex structure.

22. (canceled)

23. The display substrate according to claim 21, wherein both the first included angle and the second included angle are less than or equal to 15 degrees; or
wherein in the same convex structure, the plurality of convex structure segments comprises a plurality of convex structure combinations, at least two interconnected convex structure segments are comprised in a same convex structure combination, and the two adjacent convex structure segments form a third included angle toward the display area or toward the first barrier structure.

24. (canceled)

25. A display device, comprising the display substrate according to claim 1.
